(19) United States
(12) Patent Application Publication
(10) Pub. No.: US 2003/0141520 A1
(43) Pub. Date: Jul. 31, 2003

(54) Semiconductor device manufacturing method

(76) Inventor: Yasuhiro Miyakawa, Tokyo (JP)

Correspondence Address: VOLENTINE FRANCOS, PLLC, Suite 150, 12200 Sunrise Vally Drive, Reston, VA, 20191, US

(21) Appl. No.: 10/059,220

(22) Filed: Jan. 31, 2002

(51) Int. Cl. H01L 31/0328

(52) U.S. Cl. 257/200

(57) ABSTRACT

An n-type impurity (ions) is implanted into a cell P-well 104 through contact holes 161 to form n-type diffusion layers 171. At this time, the ranges over which no n-type impurity diffusion zone 171 is to be formed are all covered by a third silicon oxide film 151 and, as a result, no n-type impurity is implanted over these ranges. In addition, since the contact holes 161 are formed between transfer gates 111 through self-alignment, the n-type impurity diffusion zones 171 are formed at specific positions with a high degree of accuracy even in a highly miniaturized DRAM. Furthermore, since the transfer gates 111 are each provided with a side wall 115 constituted of a silicon nitride stopper film 123 and a second silicon oxide film 121, the n-type impurity is not implanted into the transfer gates. Thus, a manufacturing method that makes it possible to manufacture a semiconductor device achieving outstanding data retention characteristics and capable of sustaining a specific threshold voltage level while minimizing the increase in the production costs is provided.

### BACKGROUND OF THE INVENTION

1. Field of the Invention

The present invention relates to a semiconductor device manufacturing method.

2. Description of the Related Art

The capability of a semiconductor memory for holding stored data over an extended period of time (data retention) is one of the crucial factors that affect the performance of the semiconductor memory. The structure illustrated in FIG. 11 is adopted in a semiconductor memory in the related art to improve the data retention characteristics.

FIG. 11 presents a sectional view of elements in the memory cell array area provided in a DRAM (dynamic random access memory), which is taken while the manufacturing process is in progress. An element isolating area 302 is formed at a silicon substrate 301 and this element isolating area 302 electrically isolates the memory cell array area from a peripheral circuit area or the like (not shown). In addition, an N-well 303 is formed at the memory cell array area of the silicon substrate 301, with a cell P-well 304 formed inside the N-well 303.

A plurality of transfer gates 311 are formed on the silicon substrate 301. The transfer gates 311 each include a silicon oxide film 313 at the upper position and a side wall 315 at the side. Each transfer gate 311 is covered by a silicon oxide film 321 which functions as an insulating film.

A plurality of contact holes 331 are formed at the silicon oxide film 321, each extending from the surface of the silicon oxide film 321 and reaching the upper surface of the cell P-well 304 through the gap between the individual transfer gates 311. The contact holes 331 are ultimately filled with, for instance, polycrystalline silicon. A plurality of capacitors (not shown) for holding data are formed at the surface of the silicon oxide film 321. The capacitors are each electrically connected to one of the transfer gates 311 via the polycrystalline silicon filling the corresponding contact hole 331.

An n-type impurity diffusion zone 341 is formed at the cell P-well 304 over the range in which each contact hole 331 is formed. Since both the polycrystalline silicon filling the contact holes 331 and the polycrystalline silicon constituting the capacitors that hold data constitute n⁺ regions, an n⁺/n/p junction is formed by the polycrystalline silicon film, the n-type impurity diffusion zone 341 and the cell P-well 304. As a result, the electrical charge stored at each capacitor does not flow out toward the silicon substrate 101 readily except for during a data read. By forming the n-type impurity diffusion zones 341 as described above, an improvement in the data retention characteristics is achieved in the DRAM.

The DRAM product is completed by implementing a step in which the contact holes 331 are filled with the polycrystalline silicon and a step in which bit lines are formed on the DRAM shown in FIG. 11 undergoing the manufacturing process.

The step for implanting ions to form the n-type impurity diffusion zones 341 is implemented before the formation of the silicon oxide film 321 in the related art for the following reasons.

Provided that the individual contact holes 331 have been formed at the silicon oxide film 321 in conformance to the stipulated design values, the ion seed is implanted into the cell P-well 304 via the contact holes 331 to form the n-type impurity diffusion zones 341 over the correct ranges.

However, as the need to achieve higher integration and further miniaturization of semiconductor devices has increased in recent years, even very slight errors occurring with regard to the positions at which the contact holes 331 are formed or with respect to their bore diameter can no longer be disregarded. Even if the positions and the bore diameter of the contact holes 331 which have been formed deviate from the design values only by a very small degree, the positional margin that must be assured between the contact holes 331 and the transfer gates 311 becomes reduced. In some cases, the side walls 315 may be ground and become thinner during the formation of the contact holes 311. If ions are implanted in this state, the ion seed may enter into the transfer gates 311 as well as the cell P-well 304 to result in degradation of the characteristics of the individual transfer gates 311.

Accordingly, the ion implantation step is implemented to form the n-type impurity diffusion zones 341 prior to the formation of the silicon oxide film 321, i.e., while the side walls 315 still maintain a predetermined film thickness, in the related art. By adopting this method, it is ensured that no ions are implanted into the transfer gates 311 and, thus, desired characteristics are maintained at the transfer gates 311.

However, since the n-type impurity diffusion zones 341 are formed only in the memory cell array area, it is necessary to form a mask for covering the area (not shown) other than the memory cell array area during the formation of the n-type impurity diffusion zones 341 in the manufacturing method in the related art. The use of this mask allows the ion seed to be selectively implanted only into the memory cell array area. However, a photolithography step and an etching step must be implemented specifically to form the mask. In other words, additional steps, i.e., the photolithography step and the etching step, must be implemented as well as the ion implantation step, in order to improve the retention characteristics of the DRAM in the related art. This inevitably leads to an increase in the DRAM production cost.

In addition, if the n-type impurity diffusion zones 341 are formed at a relatively early stage as in the manufacturing method in the related art, the n-type impurity constituting each n-type impurity diffusion zone 341 becomes diffused to an excessive degree during the subsequent heat treatment, which must be implemented several times. Such excessive diffusion of the n-type impurity may result in a lowered threshold voltage at each transfer gate 311.

### SUMMARY OF THE INVENTION

An object of the present invention, which has been completed by addressing the problems of the related art discussed above, is to provide a semiconductor manufacturing method that makes it possible to manufacture a semiconductor device achieving good data retention characteristics and capable of sustaining a predetermined threshold voltage while minimizing any increase in the production cost.

In order to achieve the object described above, in a first aspect of the present invention, a semiconductor device manufacturing method comprising a gate electrode formation step in which a plurality of gate electrodes (transfer gates) are formed on a substrate, an oxide film formation step in which an oxide film is formed to cover the surfaces of the gate electrodes and the surface of the substrate, a stopper film formation step in which a stopper film is formed over the oxide film, a insulating film formation step in which a insulating film is formed over the stopper film, an opening formation step in which openings positioned between the gate electrodes are formed at the insulating film by etching the insulating film with the stopper film acting as an etching stopper and ions implantation step in which ions are implanted into the substrate and impurity diffusion zones are formed at the substrate by using the insulating film having the plurality of openings therein as a mask is provided.

When this method is adopted, in which the insulating film is used as a mask when implanting ions into the substrate, the necessity for forming a separate mask is eliminated. As a result, a reduction in the number of steps to be implemented during the process of manufacturing the semiconductor device is reduced.

In addition, the correct positional margin is assured between the individual openings and the individual gate electrodes. As a result, the ions to be implanted into the substrate through the openings are not inadvertently implanted into the gate electrodes.

### BRIEF DESCRIPTION OF THE DRAWINGS

The above and other features of the invention and the concomitant advantages will be better understood and appreciated by persons skilled in the field to which the invention pertains in view of the following description given in conjunction with the accompanying drawings which illustrate preferred embodiments. In the drawings:

FIG. 1 is a sectional view (1) of a DRAM manufacturing step implemented in an embodiment of the present invention;

FIG. 2 is a sectional view (2) of a DRAM manufacturing step implemented in the embodiment of the present invention;

FIG. 3 is a sectional view (3) of a DRAM manufacturing step implemented in the embodiment of the present invention;

FIG. 4 is a sectional view (4) of a DRAM manufacturing step implemented in the embodiment of the present invention;

FIG. 5 is a sectional view (5) of a DRAM manufacturing step implemented in the embodiment of the present invention;

FIG. 6 is a sectional view (6) of a DRAM manufacturing step implemented in the embodiment of the present invention;

FIG. 7 is a sectional view (7) of a DRAM manufacturing step implemented in the embodiment of the present invention;

FIG. 8 is a plan view of the pattern formed at the first mask used in the DRAM production in the embodiment of the present invention;

FIG. 9 is a plan view of the pattern formed at the second mask used in the DRAM production in the embodiment of the present invention;

FIG. 10 is a plan view of the pattern formed at the third mask used in the DRAM production in the embodiment of the present invention; and

FIG. 11 presents a sectional view showing the structure adopted in a DRAM in the related art.

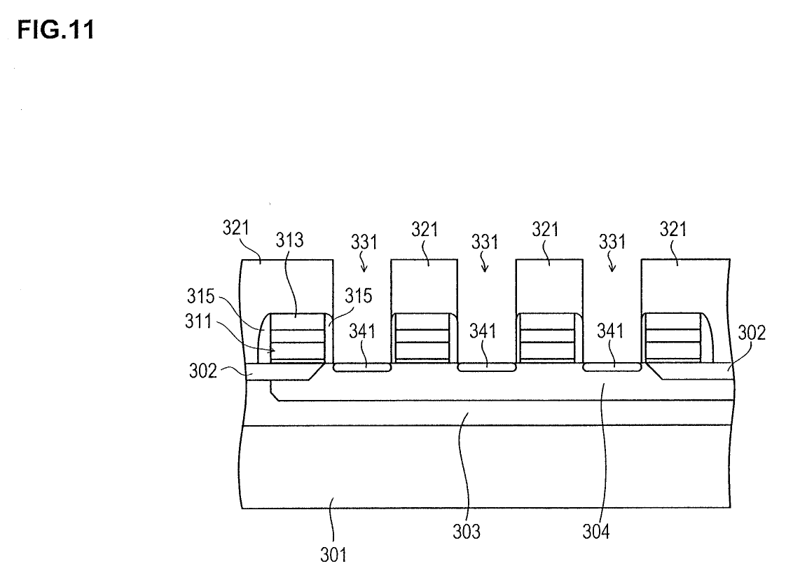

### DETAILED DESCRIPTION OF THE PREFERRED EMBODIMENT

The following is a detailed explanation of the preferred embodiment of the semiconductor manufacturing method according to the present invention, given in reference to the attached drawings. It is to be noted that the same reference numerals are assigned to components having roughly identical functions and structural features in the following explanation and the attached drawings to preclude the necessity for a repeated explanation thereof.

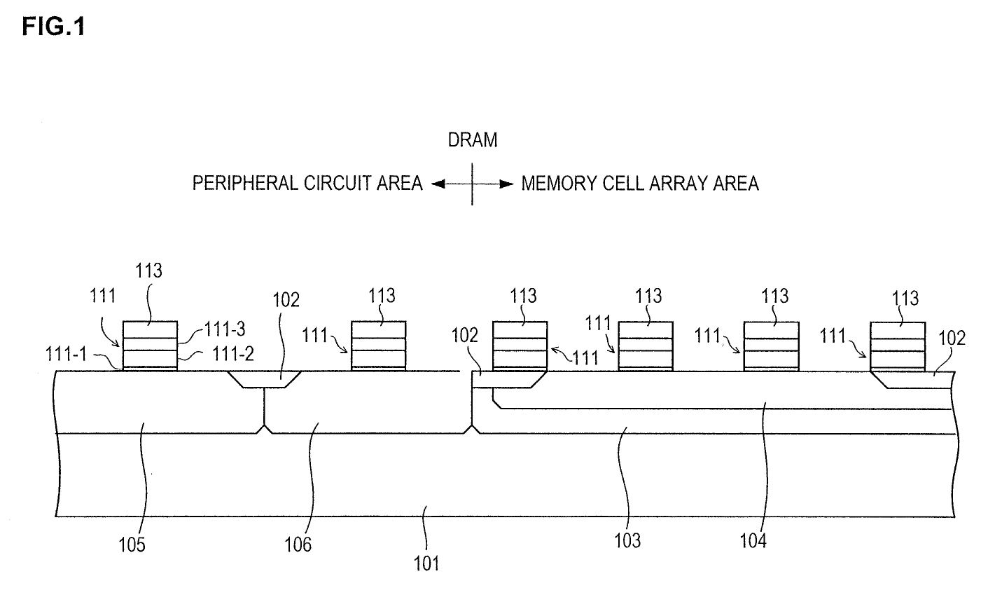

FIGS. 1˜7 present sectional views of the steps implemented to manufacture a DRAM which constitutes the semiconductor device achieved in the embodiment of the present invention. It is to be noted that the figures show the sectional views of a memory cell array area and a peripheral circuit area provided at the DRAM.

(step 1) (FIG. 1) Element isolating areas 102 are formed on a silicon substrate 101. An N-well 103 is formed in the memory cell array area, and a cell P-well 104 is formed inside the N-well 103. An N-well 105 and a P-well 106 are formed in the peripheral circuit area.

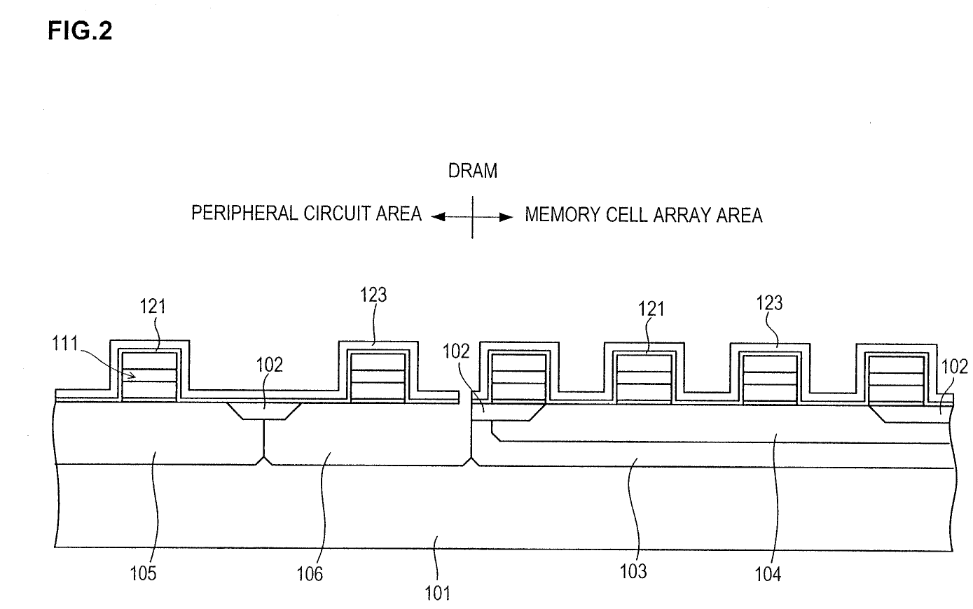

(step 2) (FIG. 2) A plurality of transfer gates 111 are formed in the memory cell array area and the peripheral circuit area. The transfer gates 111 are each constituted of a gate insulating film 111-1, a polycrystalline silicon film (with a film thickness of 120 nm) 111-2 and a tungsten silicide film (with a film thickness of 80 nm) 111-3. In addition, each transfer gate 111 includes a first silicon oxide film (with a film thickness of 250 nm) 113 formed at the upper position.

(step 3) (FIG. 2) A second silicon oxide film (with a film thickness of 20 nm) 121 is deposited over the entire surface and a silicon nitride stopper film (with a film thickness of 40 nm) 123 is deposited over the entire surface of the second silicon oxide film 121. The silicon nitride film 123 later functions as an etching stopper film when forming openings 151a at a third silicon oxide film 151 (layer insulating film) which is to be formed over the silicon nitride film 123. In the embodiment, the silicon nitride film 123 is utilized as an etching stopper film. When the silicon nitride film 123 is utilized as an etching stopper film, it is desirable to form the second silicon oxide film 121 between the gate electrodes 111 and the silicon nitride film 123 in order to prevent a charge leak from the gate electrodes 111.

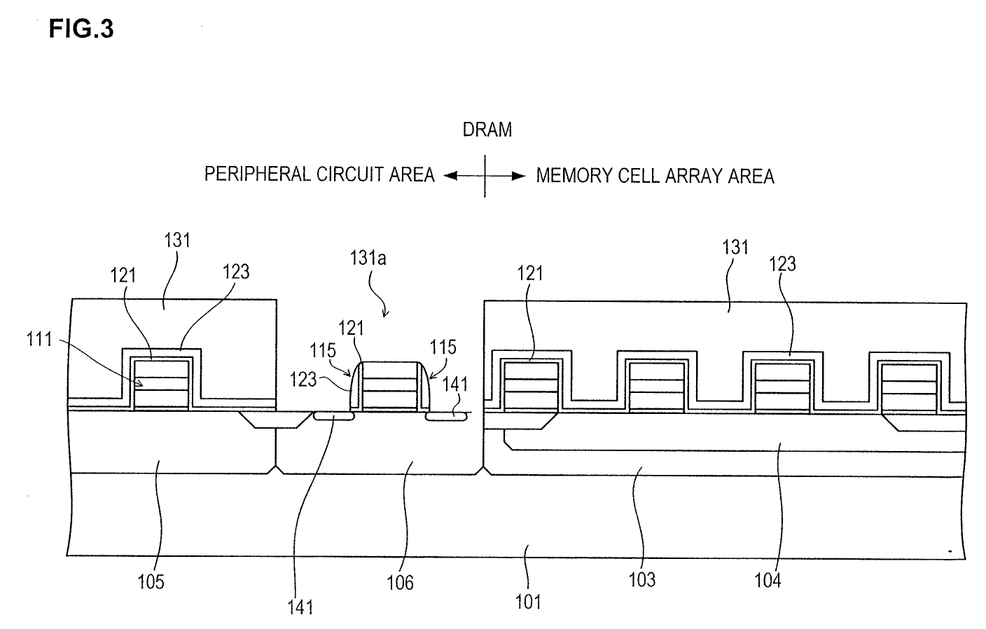

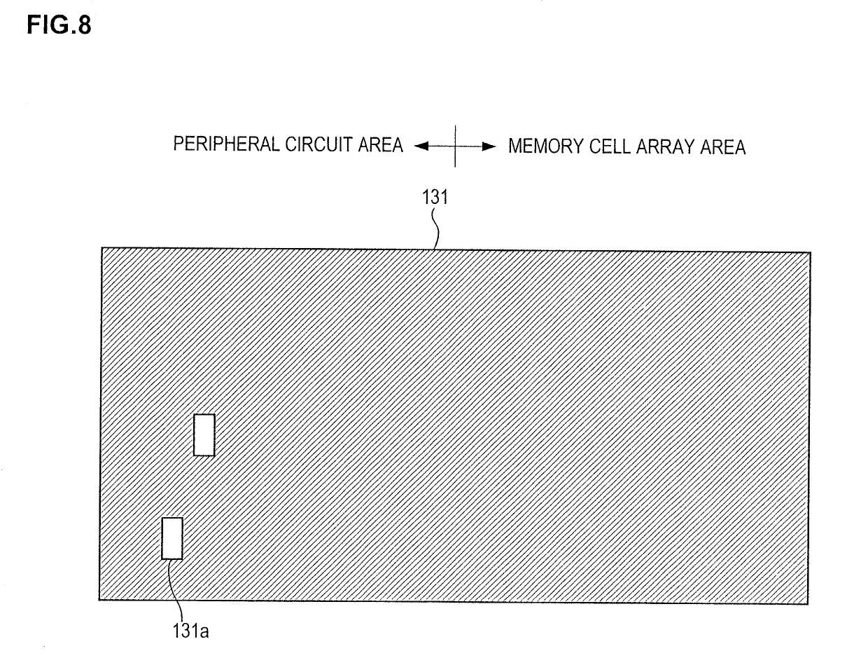

(step 4) (FIG. 3, FIG. 8) After forming a resist film, a first mask 131 is obtained by patterning the resist film through photolithography. FIG. 8 is a plan view showing the positions at which openings are made in the first mask 131. As shown in FIGS. 3 and 8, the first mask 131 includes a plurality of openings 131a formed at positions corresponding to the positions of the P-wells 106 in the peripheral circuit area.

(step 5) (FIG. 3) The silicon nitride stopper film 123 and the second silicon oxide film 121 at the openings 131a of the first mask 131 are anisotropically etched to expose the surface of the P-well 106. Through this anisotropic etching process, a side wall 115 constituted of the silicon nitride stopper film 123 and the second silicon oxide film 121 is formed at the side of the transfer gate 111 at each opening 131a.

(step 6) (FIG. 3) An n-type impurity As⁺ is implanted to the P-well 106 through ion implantation to form an n⁺-type impurity diffusion zone. The ions are implanted with the dose quantity set to 3.0×10¹⁵ cm⁻² and the acceleration energy set to 50 keV.

(step 7) The first mask 131 is removed through ashing.

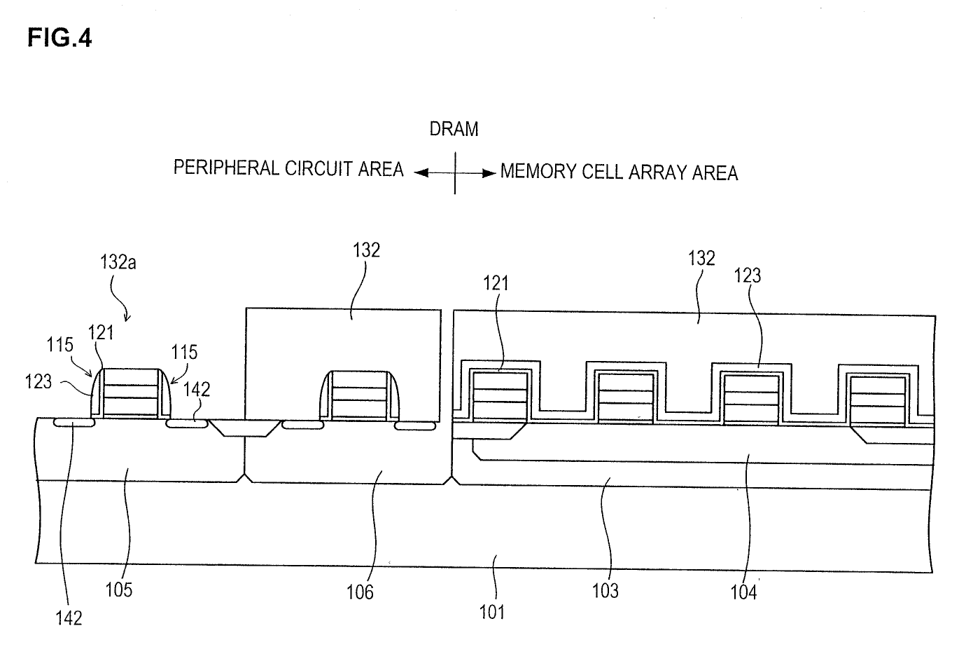

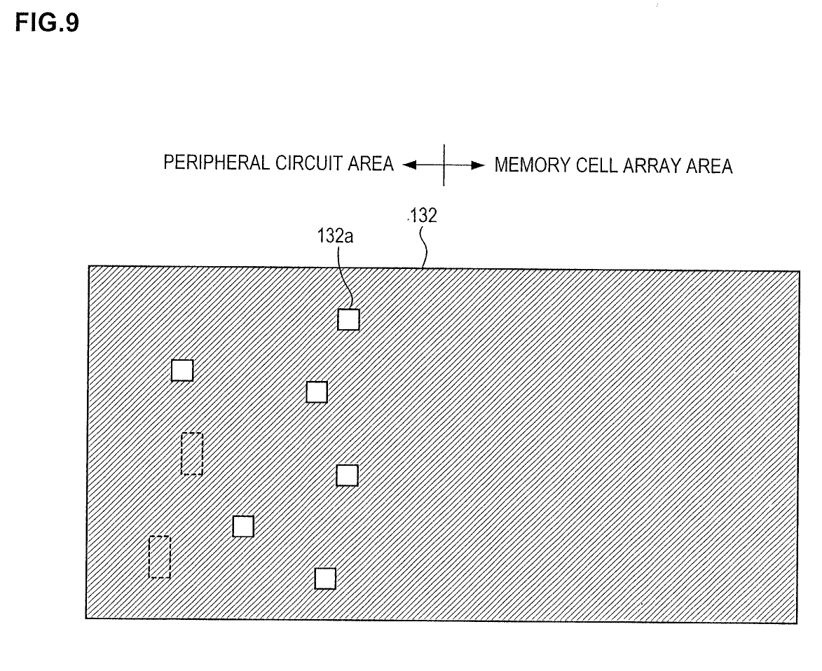

(step 8) (FIG. 4, FIG. 9) After forming a resist film, the resist film is patterned to form a second mask 132 through photolithography. FIG. 9 is a plan view showing the positions at which openings are formed at the second mask 132. It is to be noted that the openings 131a at the first mask 131 mentioned earlier are indicated by dotted lines for reference in FIG. 9. As shown in FIGS. 4 and 9, the second mask 132 includes a plurality of openings 132a formed at positions corresponding to the N-well 105 in the peripheral circuit area.

(step 9) (FIG. 4) The silicon nitride stopper film 153 and the second silicon oxide film 121 at the openings 132a of the second mask 132 are anisotropically etched to expose the surface of the P-well 106. Through this anisotropic etching process, a side wall 115 constituted of the silicon nitride stopper film 123 and the second silicon oxide film 121 is formed at the side of the transfer gate 111 at each opening 132a.

(step 10) (FIG. 4) A p-type impurity BF²⁺ is implanted to the N-well 105 through ion implantation to form a p⁺-type impurity diffusion zone 142. The ions are implanted with the dose quantity set to 1.0×10¹⁵ cm⁻² and the acceleration energy set to 30 keV.

(step 11) The second mask 132 is removed through ashing.

(step 12) A third silicon oxide film 151 is deposited over the entire surface and the deposited third silicon oxide film 151 is flattened.

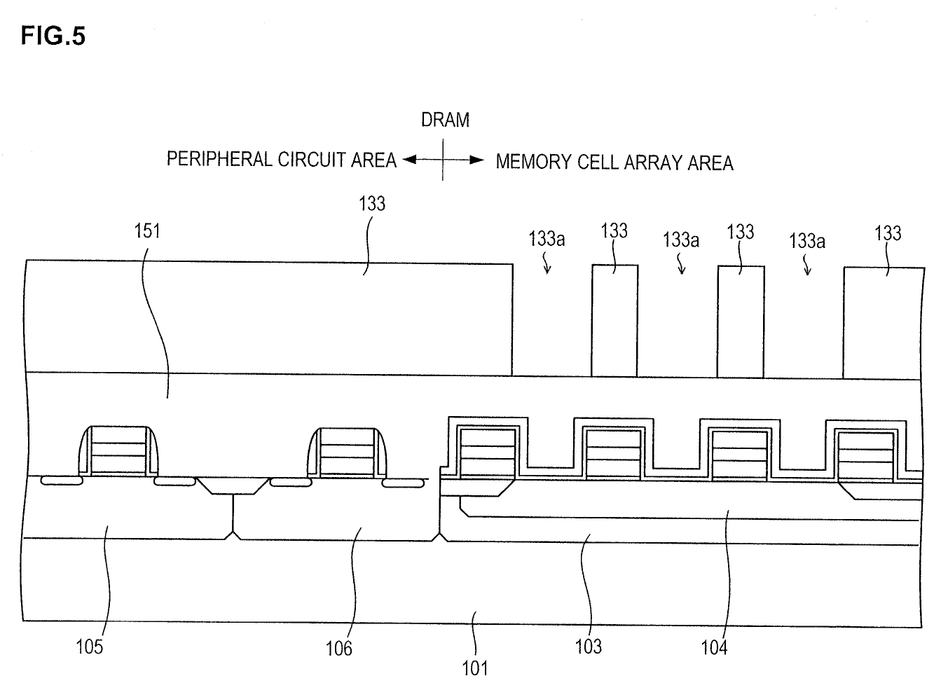

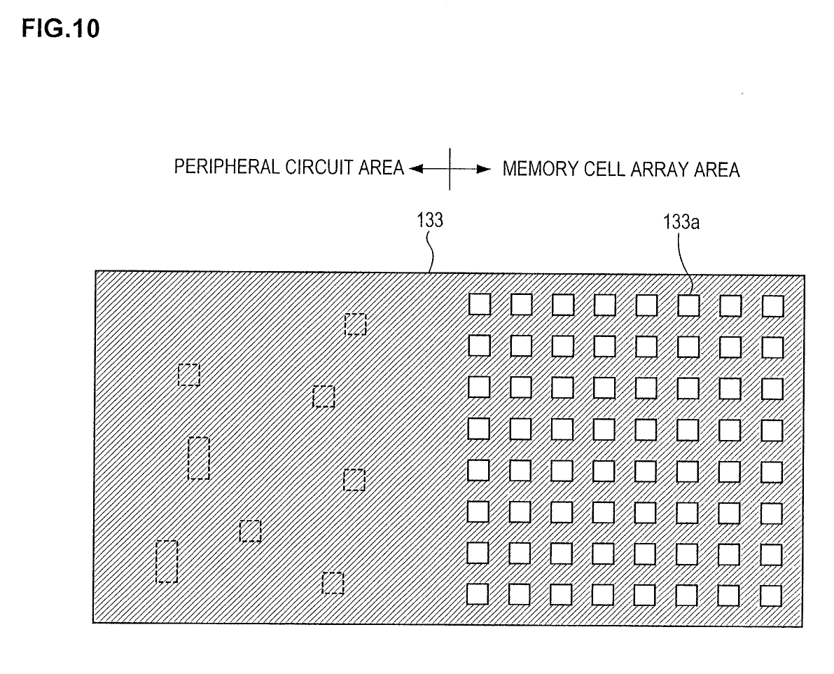

(step 13) (FIG. 5, FIG. 10) After forming a resist film, the resist film is patterned to form a third mask 133 through photolithography. FIG. 10 is a plan view showing the positions at which openings are formed at the third mask 133. It is to be noted that the openings 131a at the first mask 131 and the openings 132a at the second mask 132 mentioned earlier are indicated by dotted lines for reference in FIG. 10. As shown in FIGS. 5 and 10, the third mask 133 includes a plurality of openings 133a formed at positions corresponding to the positions cell P-well 104 in the memory cell array area.

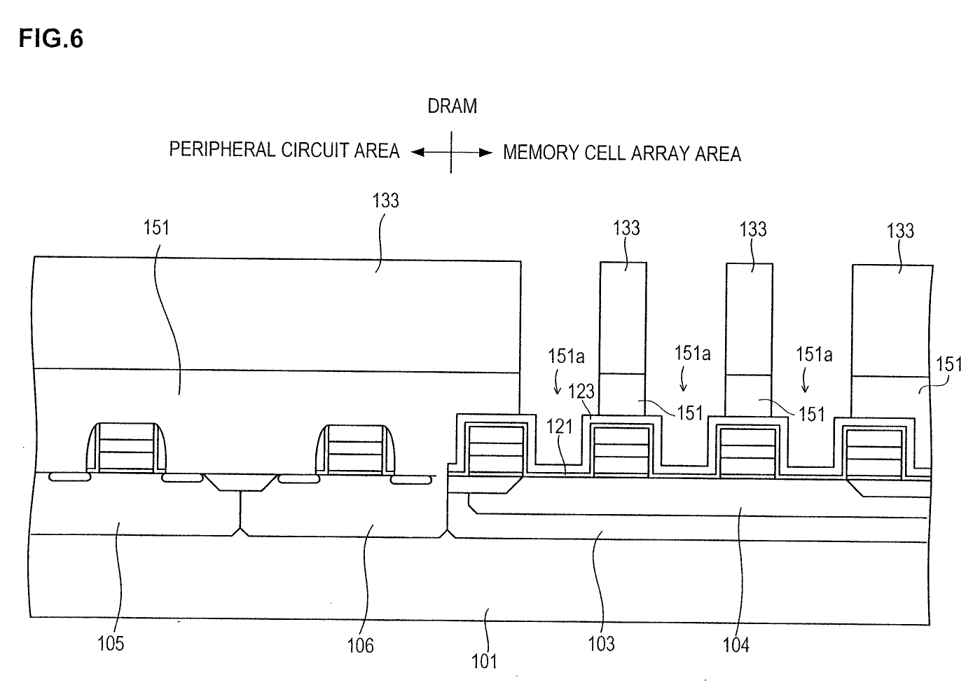

(step 14) (FIG. 6) The third silicon oxide film 151 is removed through etching at the individual openings 133a of the third mask 133. At this time, the silicon nitride stopper film 123 acts as an etching stopper. Thus, openings 151a are formed through self-alignment in the gaps between the individual transfer gates 111 without any misalignment at the third silicon oxide film 151.

(step 15) The third mask 133 is removed through ashing.

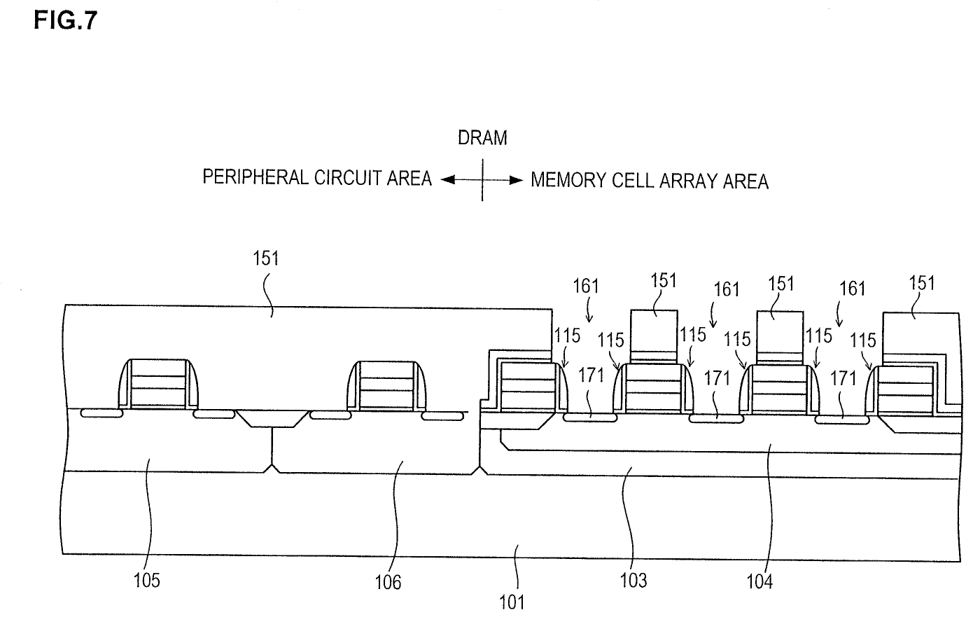

(step 16) (FIG. 7) The silicon nitride stopper film 123 and the second silicon oxide film 121 are anisotropically etched at the openings 151a of the third silicon oxide film 151 to expose the surface of the cell P-well 104. As a result, contact holes 161 are formed through self-alignment without any positional misalignment in the gaps between the individual transfer gates 111. In addition, a side wall 115 constituted of the silicon nitride stopper film 123 and the second silicon oxide film 121 is formed at the side of each transfer gate 111. (step 17) (FIG. 7) An n-type impurity As⁺ is implanted to the cell P-well 104 through ion implantation to form an n-type impurity diffusion zones 171. The ions are implanted with the dose quantity set to 5.0×10¹³ cm⁻² and the acceleration energy set to 50 keV.

Subsequently, by implementing a step for filling the contact holes 161 with a polycrystalline silicon, a step for forming bit lines and the like, the DRAM is completed as a product.

As described above, in the DRAM and the manufacturing method thereof achieved in the embodiment of the present invention, the n-type impurity diffusion zones 171 are formed immediately before the contact holes 161 are filled with the polycrystalline silicon, i.e., the timing with which they are formed is delayed as much as possible. As a result, the extent to which the n-type impurity in the n-type impurity diffusion zones 171 becomes diffused during the heat treatment and the like, which are implemented separately is minimized. Consequently, the threshold voltage at the transfer gates 111 is not lowered and desired characteristics are maintained at the transfer gates 111.

In addition, in the DRAM and the manufacturing method thereof achieved in the embodiment of the present invention, the n-type impurity (ions) is implanted into the cell P-well 104 through the contact holes 161 to form the n-type impurity diffusion zones 171. At this time, since the ranges over which no n-type impurity diffusion zone 171 is to be formed are covered by the third silicon oxide film 151 to disallow implantation of the n-type impurity into these ranges. Furthermore, since the contact holes 161 are formed between the transfer gates 111 through self-alignment, the n-type impurity diffusion zones 171 are formed at a predetermined positions with a high degree of accuracy even in a highly miniaturized DRAM. Moreover, since the transfer gates 111 each include the side wall 115 constituted of the silicon nitride stopper film 123 and the second silicon oxide film 121, no n-type impurity is implanted into the transfer gates.

The third silicon oxide film 151 is used as a insulating film. In the DRAM and the manufacturing method thereof achieved in the embodiment of the present invention, the film which is an essential structural component of the DRAM is used as a mask when implanting the n-type impurity (ions) to form the n-type impurity diffusion zones 171. In other words, it is not necessary to form a separate mask to be used when implanting the n-type impurity over specific ranges at which the cell P-well 104. This eliminates the need for implementing a photolithography step for forming a special mask, thereby achieving a reduction in the DRAM production cost.

While an explanation is given above on the DRAM manufacturing method achieved in the embodiment of the present invention, similar advantages and additional advantages may be achieved by adopting one of the manufacturing methods (variations 1˜3) achieved by changing the order in which (step 15)˜(step 17) are implemented as detailed below.

Variation 1

(step 15 (1)) The third mask 133 is removed through ashing.

(step 16 (1)) n-type impurity diffusion zones 171 are formed by implanting an n-type impurity As⁺ into the cell P-well 104 through ion implantation. During this process, while the cell P-well 104 is covered by the silicon nitride stopper film 123 and the second silicon oxide film 121 at the openings 133a of the third mask 133, the film thicknesses of the silicon nitride stopper film 123 and the second silicon oxide film 121 are respectively 40 nm and 20 nm, and thus, the n-type impurity As⁺ is allowed to pass through the silicon nitride stopper film 123 and the second silicon oxide film 121 to reach the cell P-well 104 by adjusting the dose quantity and the acceleration energy. Since the silicon nitride stopper film 123 and the second silicon oxide film 121 are formed over small thicknesses as described above, it is possible to accurately control the depth to which the n-type impurity diffusion zones 171 are formed at the cell P-well 104.

(step 17 (1)) The silicon nitride stopper film 123 and the second silicon oxide film 121 are anisotropically etched at the openings 151a of the third silicon oxide film 151 to expose the surface of the cell P-well 104. As a result, contact holes 161 are formed through self-alignment without any positional misalignment in the gaps between the individual transfer gates 111. In addition, a side wall 115 constituted of the silicon nitride stopper film 123 and the second silicon oxide film 121 is formed at the side of each transfer gate 111.

In variation 1, the transfer gates 111 formed near the openings 151a of the third silicon oxide film 151 are covered by the silicon nitride stopper film 123 and the second silicon oxide film 121 both of which have not been etched, when the n-type impurity As⁺ is implanted into the cell P-well 104. As a result, the entry of the n-type impurity As⁺ into the transfer gates 111 is prevented even more effectively.

It is to be noted that (step 15 (1)) may be implemented between (step 16 (1)) and (step 17 (1)), instead. In this case, the n-type impurity As⁺ is implanted into the cell P-well 104 while the third mask 133 is still present. Thus, the entry of the n-type impurity As⁺ into the third silicon oxide film 151 is prevented.

Alternatively, (step 15 (1)) may be implemented after (step 17 (1)). In this case, the n-type impurity As⁺ is implanted into the cell P-well 104 with the third mask 133 still present and then the silicon nitride stopper film 123 and the second silicon oxide film 121 are anisotropically etched with the third mask 133 still present. Thus, the entry of the n-type impurity As⁺ into the third silicon oxide film 151 is prevented and the upper surface of the third silicon oxide film 151 is kept in good condition without being damaged while anisotropically etching the silicon nitride stopper film 123 and the second silicon oxide film 121.

Variation 2

(step 15(2)) The silicon nitride stopper film 123 and the second silicon oxide film 121 are anisotropically etched at the openings 151a of the third silicon oxide film 151 to expose the surface of the cell P-well 104. As a result, contact holes 161 are formed through self-alignment without any positional misalignment in the gaps between the individual transfer gates 111. In addition, a side wall 115 constituted of the silicon nitride stopper film 123 and the second silicon oxide film 121 is formed at the side of each transfer gate 111.

(step 16(2)) The third mask 133 is removed through ashing.

(step 17(2)) n-type impurity diffusion zones 171 are formed by implanting an n-type impurity As⁺ into the cell P-well 104 through ion implantation.

In variation 2, the silicon nitride stopper film 123 and the second silicon oxide film 121 are anisotropically etched while the third mask 133 is still present. Consequently, the upper surface of the third silicon oxide film 151 is kept in good condition without being damaged during the anisotropic etching process.

Alternatively, (step 16 (2)) may be implemented after (step 17 (2)). In this case, the silicon nitride stopper film 123 and the second silicon oxide film 121 are anisotropically etched with the third mask 133 still present and the n-type impurity As⁺ is implanted into the cell P-well 104 with the third mask 133 still present. As a result, the upper surface of the third silicon oxide film 151 is kept in good condition without being damaged while anisotropically etching the silicon nitride stopper film 123 and the second silicon oxide film 121. Furthermore, the entry of the n-type impurity As⁺ into the third silicon oxide film 151 is prevented.

Variation 3

(step 15 (3)) The third mask 133 is removed through ashing.

(step 16 (3)) The silicon nitride stopper film 123 is anisotropically etched at the openings 151a of the third silicon oxide film 151. At this time, the second silicon oxide film 121 is used as an etching stopper.

(step 17 (3)) n-type impurity diffusion zones 171 are formed by implanting an n-type impurity As⁺ into the cell P-well 104 through ion implantation. While the cell P-well 104 is covered by the second silicon oxide film 121 at the openings 133a at the third mask 133 during this process, the film thickness of the second silicon oxide film 121 is 20 nm, and thus, the n-type impurity As⁺ is allowed to pass through the second silicon oxide film 121 to reach the cell P-well 104 by adjusting the dose quantity and the acceleration energy.

(step 18 (3)) The second silicon oxide film 121 is anisotropically etched at the openings 151a of the third silicon oxide film 151 to expose the surface of the cell P-well 104. As a result, contact holes 161 are formed through self-alignment without any positional misalignment in the gaps between the individual transfer gates 111. In addition, a side wall 115 constituted of the silicon nitride stopper film 123 and the second silicon oxide film 121 is formed at the side of each transfer gate 111.

In variation 3, the silicon nitride stopper film 123 and the second silicon oxide film 121 are etched at two separate stages. In this method, the cell P-well 104 is covered by the second silicon oxide film 121 having a 20 nm film thickness alone when implanting the n-type impurity As⁺ into the cell P-well 104. Thus, compared to variations 1 and 2 in which the n-type impurity As⁺ is implanted into the cell P-well 104 over the silicon nitride stopper film 123 and the second silicon oxide film 121, the depth of the n-type impurity diffusion zones 171 formed at the cell P-well 104 can be controlled with a higher degree of accuracy.

It is to be noted that (step 15 (3)) may be implemented after (step 16 (3)). In this case, the silicon nitride stopper film 123 is anisotropically etched while the third mask 133 is still present. Consequently, the upper surface of the third silicon oxide film 151 is kept in good condition without being damaged during the anisotropic etching process.

In addition, (step 15 (3)) may be implemented after (step 17 (3)) instead. In this case, the n-type impurity As⁺ is implanted into the cell P-well 104 while the third mask 133 is still present. Thus, the entry of the n-type impurity As⁺ into the third silicon oxide film 151 is prevented.

Alternatively, (step 15 (3)) may be implemented after (step 18 (3)). In this case, the silicon nitride stopper film 123 and the second silicon oxide film 121 are anisotropically etched with the third mask 133 still present and the n-type impurity As⁺ is implanted into the cell P-well 104 with the third mask 133 still present. As a result, the upper surface of the third silicon oxide film 151 is kept in good condition without being damaged while anisotropically etching the silicon nitride stopper film 123 and the second silicon oxide film 121. Furthermore, the entry of the n-type impurity As⁺ into the third silicon oxide film 151 is prevented.

While the invention has been particularly shown and described with respect to preferred embodiment thereof by referring to the attached drawings, the present invention is not limited to this example and it will be understood by those skilled in the art that various changes in form and detail may be made therein without departing from the spirit, scope and teaching of the invention.

As explained above, a semiconductor device achieving outstanding data retention characteristics is provided according to the present invention. In addition, a reduction in the costs to be incurred for the production of the semiconductor device is achieved. Moreover, the present invention sustains various other characteristics at desirable levels while improving the data retention characteristics.

What is claimed is:

1. A semiconductor device manufacturing method comprising;
providing a semiconductor substrate which has a well of a first conductivity type;
forming a plurality of gate electrodes on the well of said substrate;
forming a stopper film over said electrodes;
forming an insulating film over said stopper film, said insulating film having an etch rate grater than that of said stopper film;
etching said insulating film to form a plurality of openings which positioned between said gate electrodes and exposed the surface of the substrate; and
forming a plurality of impurity diffusion zones by implanting ions of a second conductivity type into the well of the substrate, wherein the ions are implanted through said plurality of openings.

2. A semiconductor device manufacturing method according to claim 1, wherein said stopper film formed at said openings is removing through etching before said ions are implemented.

3. A semiconductor device manufacturing method according to claim 1, wherein said stopper film formed at said openings is removing through etching after said ions are implemented.

4. A semiconductor device manufacturing method according to claim 1, further comprising;
forming plugs by embedding a wiring material in said openings; and
forming a plurality of capacitors on said insulating film, said capacitors are electrically connected with said gate electrodes via said plugs and said impurity diffusion zones.

5. A semiconductor device manufacturing method according to claim 4, wherein said impurity diffusion zones prevent electrical charges stored at said capacitors from flowing out.

6. A semiconductor device manufacturing method according to claim 1, further comprising;
forming an oxide film to cover a surfaces of said gate electrodes and a surface of said substrate before said stopper film is formed, wherein said stopper film is a silicon nitride film.

7. A semiconductor device manufacturing method according to claim 1, further comprising;
removing through etching said stopper film and said oxide film formed at said openings before said ions are implanted.

8. A semiconductor device manufacturing method according to claim 7, wherein;
an etching mask formed on said insulating film to form said openings is removed through ashing before said stopper film and said oxide film are removed through etching.

9. A semiconductor device manufacturing method according to claim 7, wherein;
an etching mask formed on said insulating film to form said openings is removed through ashing after said stopper film and said oxide film are removed through etching and before said ions are implanted.

10. A semiconductor device manufacturing method according to claim 7, wherein;
an etching mask formed on said insulating film to form said openings is removed through ashing after said ions are implanted.

11. A semiconductor device manufacturing method according to claim 1, further comprising;
removing through etching said stopper film and said oxide film formed at said openings after said ions are implanted.

12. A semiconductor device manufacturing method according to claim 11, wherein;
an etching mask formed on said insulating film to form said openings is removed through ashing before said ions are implanted.

13. A semiconductor device manufacturing method according to claim 11, wherein:
an etching mask formed on said insulating film to form said openings is removed through ashing after said ions are implanted and before said stopper film and said oxide film are removed through etching.

14. A semiconductor device manufacturing method according to claim 11, wherein;
an etching mask formed on said insulating film to form said openings is removed through ashing after said stopper film and said oxide film are removed through etching.

15. A semiconductor device manufacturing method according to claim 1, further comprising;
removing through etching said stopper film formed at said openings before said ions are implanted; and
removing through etching said oxide film formed at said openings after said ions are implanted.

16. A semiconductor device manufacturing method according to claim 15, wherein:
an etching mask formed on said insulating film to form said openings is removed through ashing before said stopper film is removed through etching.

17. A semiconductor device manufacturing method according to claim 15, wherein:
an etching mask formed on said insulating film to form said openings is removed through ashing after said stopper film is removed through etching and before said ions are implanted.

18. A semiconductor device manufacturing method according to claim 15, wherein:
an etching mask formed on said insulating film to form said openings is removed through ashing after said ions are implanted and before said oxide film is removed through etching.

19. A semiconductor device manufacturing method according to claim 15, wherein:
an etching mask formed on said insulating film to form said openings is removed through ashing after said oxide film is removed through etching.
